(19) United States
(12) Patent Application Publication
(10) Pub. No.: US 2025/0293500 A1
(43) Pub. Date: Sep. 18, 2025

(54) BRANCH CIRCUIT UNIT

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventor: Yusuke ISAJI, Osaka (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 18/863,141

(22) PCT Filed: May 17, 2023
(86) PCT No.: PCT/JP2023/018474

§ 371 Date: Nov. 5, 2024

(30) Foreign Application Priority Data
May 25, 2022 (JP) 2022-084924

(51) Int. Cl. H02G 3/16; H02G 3/14

(52) U.S. Cl. CPC H02G 3/16; H02G 3/14

(57) ABSTRACT

A highly versatile branch circuit unit is capable of accommodating increases and decreases in the number of branches with superior space efficiency and handling. The branch circuit unit includes a basic unit, which includes a basic branch circuit and a basic case, and at least one additional unit which each include an additional branch circuit and an additional case. The additional case is linked to the basic case. The basic branch circuit includes a basic-side branch connecting portion, and this basic side branch connecting portion is connected to the additional branch circuit. The additional branch circuit includes an additional-side branch connecting portion. When a plurality of additional units are used, the additional-side branch connecting portion of one additional unit is connected to the additional branch circuit of the other additional unit, and the additional case of the one additional unit is linked to the additional case of the other additional unit.

### TECHNICAL FIELD

The present disclosure relates to a branch circuit unit.

### BACKGROUND ART

Automobiles have conventionally been equipped with a branch circuit unit that branches (distributes) power from a power source, such as a battery pack, installed in the vehicle to a plurality of vehicle-mounted accessories. Since the number of branches to accessories at a branch circuit unit will vary depending on the vehicle model and grade, it has been necessary to design a dedicated branch circuit unit for each model and grade. For this reason, Patent Document 1 proposes a structure where an electrical connection box is configured to allow use in both low-grade and high-grade models, with a relay mounting unit for use in high-grade models being provided in a region that is part of the case so that additional relays can be mounted when the electrical connection box is used in a high-grade model. Additionally, Patent Document 2 proposes a structure where a main connection box is shared by low-grade and high grade models, a separate relay block is used only in high-grade models, and the separate relay block can be mounted in an empty space that is physically separated from the main connection box.

### CITATION LIST

### Patent Documents

Patent Document 1: JP 2005-185062A
Patent Document 2: JP H09-140028A

### SUMMARY OF INVENTION

### Technical Problem

However, the structure of Patent Document 1 produces a region (that is, the relay mounting region) that will remain unused in low-grade models, resulting in problems in miniaturization and efficient use of space. The structure of Patent Document 2 has an inherent problem of poor handling due to the main connection box and the relay block being separate components.

For this reason, a highly versatile branch circuit unit is disclosed that can accommodate increases and decreases in the number of branches while achieving superior space efficiency and handling.

### Solution to Problem

A branch circuit unit according to an aspect of the present disclosure includes: a basic unit including a basic branch circuit, which includes a basic-side input portion and a basic-side output portion, and a basic case that holds the basic branch circuit; and at least one additional unit including an additional branch circuit, which includes an additional-side input portion and an additional-side output portion, and an additional case that holds the additional branch circuit, wherein the basic case includes a first linked portion to which a linking portion provided on the additional case can be linked, with the basic case and the additional case being linked by linking the linking portion and the first linked portion, the additional case includes the linking portion and a second linked portion to which a linking portion can be connected, the basic branch circuit includes a basic-side branch connecting portion connected to the basic-side input portion, with the basic-side branch connecting portion being connected to the additional-side input portion of the additional branch circuit, the additional branch circuit includes an additional branch connecting portion that is connected to the additional-side input portion, and when a plurality of the additional units are used, the additional-side branch connecting portion of one additional unit, which is linked to the basic unit-side, is connected to the additional-side input portion of another additional unit, and the additional case of the one additional unit is linked to the additional case of the other additional unit by linking the linking portion of the other additional unit and the second linked portion of the one additional unit.

### Advantageous Effects of Invention

According to the present disclosure, it is possible to provide a highly versatile branch circuit unit that can accommodate increases and decreases in the number of branches while achieving superior space efficiency and handling.

### BRIEF DESCRIPTION OF DRAWINGS

FIG. 1 is a perspective view depicting a specific example of a branch circuit unit according to a first embodiment, and depicts a state where a basic unit and two additional units are held in a provisionally fixed state.

FIG. 2 is a plan view of the branch circuit unit depicted in FIG. 1.

FIG. 3 is a cross-sectional view taken along a line III-III in FIG. 2.

FIG. 4 is a cross-sectional view taken along a line IV-IV in FIG. 2.

FIG. 5 is a perspective view of a basic unit that constructs the branch circuit unit depicted in FIG. 1.

FIG. 6 is an exploded perspective view of the basic unit depicted in FIG. 5.

FIG. 7 is a perspective view of an additional unit that constructs the branch circuit unit depicted in FIG. 1.

FIG. 8 is a perspective view depicting the additional unit depicted in FIG. 7 from the rear side.

FIG. 9 is an exploded perspective view of the additional unit depicted in FIG. 7.

FIG. 10 is a perspective view depicting another specific example of a branch circuit unit according to the first embodiment, and depicts a state where a basic unit and one additional unit are held in a provisionally fixed state.

FIG. 11 is a vertical cross-sectional view depicting a state where a basic unit and two additional units are held in a fully fixed state in the branch circuit unit depicted in FIG. 1, and corresponds to FIG. 3.

FIG. 12 is a vertical cross-sectional view depicting a state where a basic unit and two additional units are held in a fully fixed state in the branch circuit unit shown in FIG. 1, and corresponds to FIG. 4.

FIG. 13 is a vertical cross-sectional view depicting a branch circuit unit according to another aspect and corresponds to FIG. 4.

### DESCRIPTION OF EMBODIMENTS

### Outline of Embodiments of the Present Disclosure

Several embodiments of the present disclosure will first be listed and described in outline.

A branch circuit unit according to an aspect of the present disclosure includes: a basic unit including a basic branch circuit, which includes a basic-side input portion and a basic-side output portion, and a basic case that holds the basic branch circuit; and at least one additional unit including an additional branch circuit, which includes an additional-side input portion and an additional-side output portion, and an additional case that holds the additional branch circuit, wherein the basic case includes a first linked portion to which a linking portion provided on the additional case can be linked, with the basic case and the additional case being linked by linking the linking portion and the first linked portion, the additional case includes the linking portion and a second linked portion to which a linking portion can be connected, the basic branch circuit includes a basic-side branch connecting portion connected to the basic-side input portion, with the basic-side branch connecting portion being connected to the additional-side input portion of the additional branch circuit, the additional branch circuit includes an additional-side branch connecting portion that is connected to the additional-side input portion, and when a plurality of the additional units are used, the additional-side branch connecting portion of one additional unit, which is linked to the basic unit-side, is connected to the additional-side input portion of another additional unit, and the additional case of the one additional unit is linked to the additional case of the other additional unit by linking the linking portion of the other additional unit and the second linked portion of the one additional unit.

The branch circuit unit according to the present disclosure includes a basic unit and at least one additional unit, and by adding additional units to the basic unit and/or adjusting the number of additional units to be added, an appropriate branch circuit unit can be constructed in keeping with the number of branches, which will differ between vehicle models and grades. In addition, since the basic unit and the additional unit are constructed separately and each have a separate branch circuit and case, a branch circuit unit corresponding to the required number of branches can be constructed with favorable space efficiency by simply adding or removing additional units according to the required number of branches. This eliminates the problem of unused space as produced with the structure according to Patent Document 1.

In addition, the basic unit and the additional unit can be linked to each other by linking a linking portion provided on the additional case to a first linked portion provided on the basic case. This means that compared to the structure according to Patent Document 2, it is possible to significantly improve handling during transportation and assembly. In addition, when a plurality of additional units are used, the additional units can be linked to each other by linking the linking portion provided on the additional case of one additional unit to the second linked portion of the additional case of another additional unit that has already been linked to the basic case. This means that an increase in the number of branches can be easily handled simply by adding additional units of the same structure, and superior handling can be achieved because the basic unit and a plurality of additional units can be linked to each other and handled as an integrated structure.

Note that the number of branches in the basic branch circuit and the additional branch circuit can be freely selected. As examples, the number of branches in the basic branch circuit may be one or a plurality of branches, and the number of branches in an additional branch circuit may be one or a plurality of branches.

It is preferable for the basic-side branch connecting portion to become disposed so as to be connectable to the additional-side input portion of the additional branch circuit by linking the linking portion and the first linked portion, and when a plurality of the additional units are added, preferable for the additional-side branch connecting portion of the one additional unit to be disposed so as to be connectable to the additional-side input portion of the other additional unit by linking the linking portion of the other additional unit and the second linked portion of the one additional unit.

Since the basic-side branch connecting portion and the additional-side input portion become disposed so as to be connectable when the linking portion and the first linked portion are linked, once the basic case and the additional case have been linked, an operation of connecting the basic-side branch connecting portion and the additional-side input portion using a bolt or the like can be performed smoothly. This means that in addition to the improvement in the handling of the basic case and the additional case, assembly operations are also improved. In addition, even when a plurality of additional units are added, by linking the linking portion of one additional unit to the second linked portion of another additional unit, the additional-side branch connecting portion of one additional unit and the additional-side input portion of the other additional unit become disposed so as to be connectable, so that when the additional cases have been linked to each other, a connection operation for the additional-side branch connecting portion and the additional-side input portion using a bolt or the like can be performed smoothly. This means that in addition to improving the handling of the basic case and the plurality of additional cases, it is also possible to improve the ease of assembly of the plurality of additional cases.

It is preferable for the linking portion to include a convex portion that protrudes outward from a surface of the additional case, and for the first linked portion and the second linked portion to both include a concave portion that is open at a surface of the basic case and the surface of the additional case, respectively, and capable of housing the convex portion. The linking portion that includes a convex portion and the first/second linked portions that include a concave portion capable of accommodating the linking portion make it possible to make the overall shape of a linked structure produced by the basic case and additional cases that have been linked by linking the linking portion and the first/second linked portions compact. In addition, when the basic unit is used on its own, the first linked portion is a concave portion that is open at the surface of the basic case, which makes it possible to prevent the first linked portion from protruding outward from the basic case and getting in the way. In the same way, even when the basic unit and an additional case are used having been linked together, the convex part that serves as the linking portion will be housed in a concave portion that is open at the surface of the basic case, which also makes it possible to avoid the linking portion from protruding outward.

It is preferable for the convex portion to include a first convex portion and a second convex portion, for the concave portion to include a first concave portion and a second concave portion, for the first convex portion provided on the additional case to be housed in the first concave portion provided in the basic case or the additional case, for either the basic case and the additional case or two additional cases to be held together in a provisionally fixed state due to the first convex portion and the first concave portion engaging each other, and for either the basic case and the additional case or the two additional cases to be placed in a fully fixed state by fastening the second convex portion, which is provided on an additional case, and the second concave portion, which is provided on the basic case or on another additional case, to each other with a bolt.

Through engagement of the first convex portion and the first concave portion, the basic case and an additional case, or two additional cases are held in a provisionally fixed state. In other words, it is possible to achieve a provisionally fixed state between a simple linking portion and first/second linked portion even before full fixing is performed when mounting in a vehicle using the proper bolts, nuts, and the like. This means that through the simple provisional fixing, it is possible to link the basic unit and an additional unit or two or more additional units during transportation for example, which further improves handling. Note that the first convex portion and the first concave portion can have any freely chosen structure as long as the portions are capable of engaging each other. As one example, the first convex portion may be configured as an elastic locking claw, and the first concave portion may be configured as a concave portion including a locking convex portion that the elastic locking claw engages, thereby locking the first convex portion and the first concave portion in engagement. In addition, the first convex portion may be configured as a press-fitted protrusion, and the second concave portion may be configured as a press-fitting hole, with the first convex portion and the first concave portion engaging each other via a press fit.

In addition, by fastening the second convex portion and the second concave portion to each other with a bolt, the basic case and the additional case, or two additional cases are held together in a fully fixed state. This means that when the branch circuit unit is mounted in a vehicle, fully fixing makes it possible to more stably maintain the link between the basic unit and the additional unit, or between two additional units.

It is preferable for the basic branch circuit to include a bus bar, for the basic-side input portion to be provided at one end of the bus bar, for the basic-side branch connecting portion to be provided at another end of the bus bar, and for an input terminal of a fuse to be connected to the one end side. A single bus bar can be used to provide the basic-side input portion and the basic-side branch connecting portion, and the input terminal of a fuse is connected to one end (the side where the basic-side input portion is provided) of this bus bar. This is advantageous in miniaturization of and reducing the number of components in the basic branch circuit and the basic unit.

It is preferable for the basic branch circuit to include a fuse connected to the basic-side input portion and for the basic-side output portion to be constructed by an output terminal of the fuse. Since the basic-side output portion of the basic branch circuit is constructed by the output terminal of the fuse, this is advantageous in miniaturization of and reducing the number of components in the basic branch circuit and the basic unit.

It is preferable for the additional branch circuit to include a bus bar, for the additional-side input portion to be provided at one end of the bus bar, for the additional-side branch connecting portion to be provided at another end of the bus bar, and for an input terminal of a fuse to be connected to the one end side. A single bus bar can be used to provide the additional-side input portion and the additional-side branch connecting portion, and the input terminal of a fuse is connected to one end (the side where the additional-side input portion is provided) of this bus bar. This is advantageous in miniaturization of and reducing the number of components in the additional branch circuit and the additional unit.

It is preferable for the additional branch circuit to include a fuse connected to the additional-side input portion, and for the additional-side output portion to be constructed by an output terminal of the fuse. Since the additional-side output portion of the additional branch circuit is constructed by the output terminal of the fuse, this is advantageous in miniaturization of and reducing the number of components in the additional branch circuit and the additional unit.

It is preferable for the linking portion and the first linked portion or the second linked portion to contact each other with an elastic member in between. Having the linking portion and the first linked portion or the second linked portion come into contact via the elastic member advantageously absorbs tolerances that can be problematic during linking. Note that the elastic member may be an elastic pad or the like provided separately from the linking portion or the first/second linked portions or may be crimped ribs or the like that is provided integrally with the linking portion or the first/second linked portions.

### Detailed Description of Embodiments of the Present Disclosure

Preferred embodiments of a branch circuit unit according to the present disclosure will now be described with reference to the drawings. Note that the present disclosure is not limited to the embodiments given here, is indicated by the range of the patent claims, and is intended to include all possible changes and modifications within the meaning and scope of the patent claims and their equivalents.

### First Embodiment

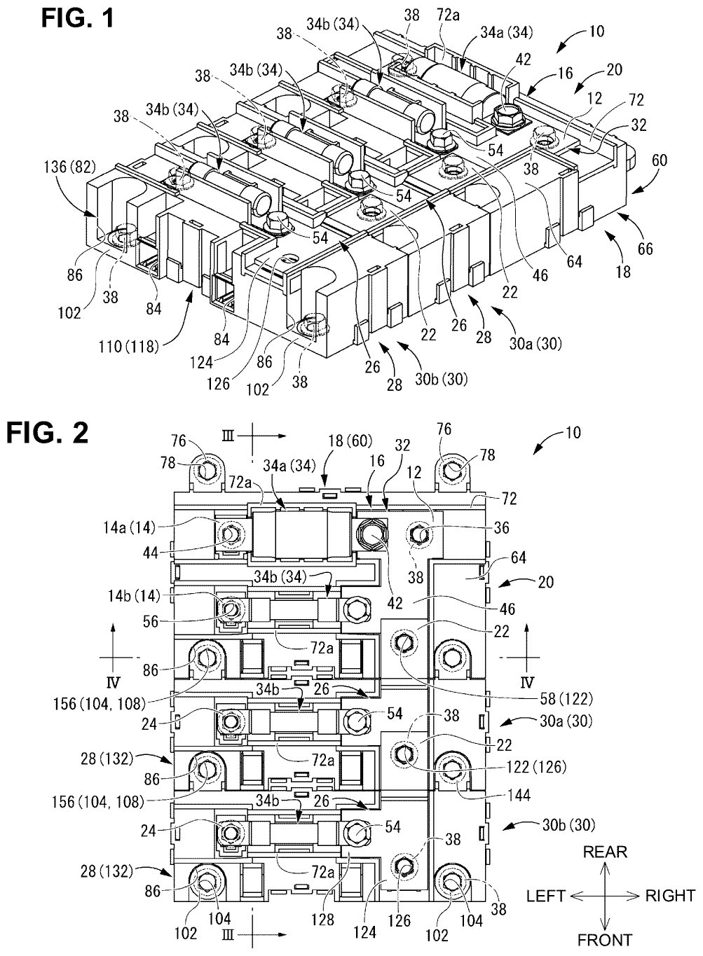

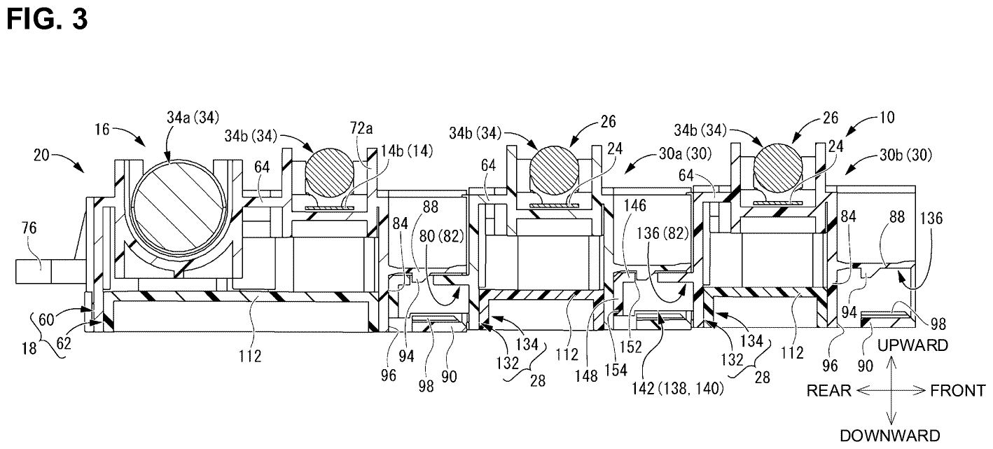

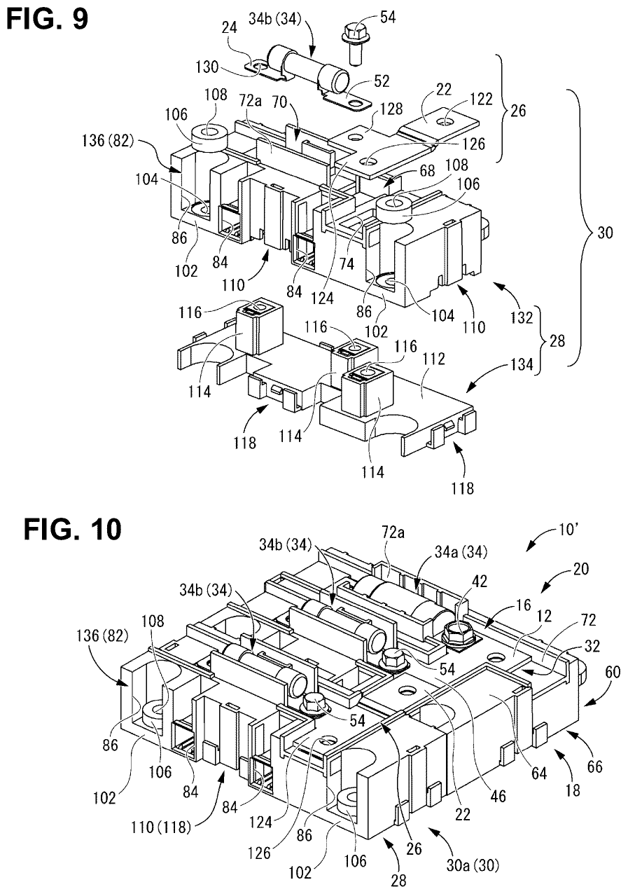

A branch circuit unit 10 according to a first embodiment of the present disclosure is described below with reference to FIGS. 1 to 12. The branch circuit unit 10 is mounted in an electric vehicle or a hybrid vehicle, and includes a circuit that branches from a battery pack, not illustrated, that serves as a power source to various conventionally known accessories, also not illustrated, such as an electric power steering system, an electric parking brake, lights, a wiper driving unit, a navigation apparatus, and an air conditioner. Note that although the branch circuit unit 10 can be placed in any orientation, in the following description, the expression “upward” refers to upward in FIG. 3, “downward” refers to downward in FIG. 3, “the front” refers to the bottom in FIG. 2, “the rear” refers to the top in FIG. 2, “left” refers to the left in FIG. 2, and “right” refers to the right in FIG. 2. Note also that for a plurality of members that are identical, reference numbers may be assigned to only some of the members and omitted for the other members.

### Branch Circuit Unit 10

The branch circuit unit 10 according to the first embodiment is equipped with a basic unit 20 including a basic branch circuit 16, which includes a basic-side input portion 12 and a basic-side output portion 14, and a basic case 18 that holds the basic branch circuit 16. The branch circuit unit 10 is also equipped with additional units 30 that each include an additional branch circuit 26, which includes an additional-side input portion 22 and an additional-side output portion 24, and an additional case 28 that holds the additional branch circuit 26. The branch circuit unit 10 is equipped with one basic unit 20 and at least one additional unit 30, and in FIGS. 1 to 4, the branch circuit unit 10 is equipped with one basic unit 20 and two additional units 30 (that is, a first additional unit 30a and a second additional unit 30b). That is, the first additional unit 30a is linked to the basic unit 20 as a “provided additional unit”, and the second additional unit 30b is further linked as “another additional unit” to the first additional unit 30a as the provided additional unit. Note that FIGS. 1 to 4 depict states where the basic unit 20 (the basic case 18) and the first additional unit 30a (the additional case 28) and the first additional unit 30a (the additional case 28) and the second additional unit 30b (the additional case 28) are respectively held in a provisionally fixed state.

### Basic Branch Circuit 16

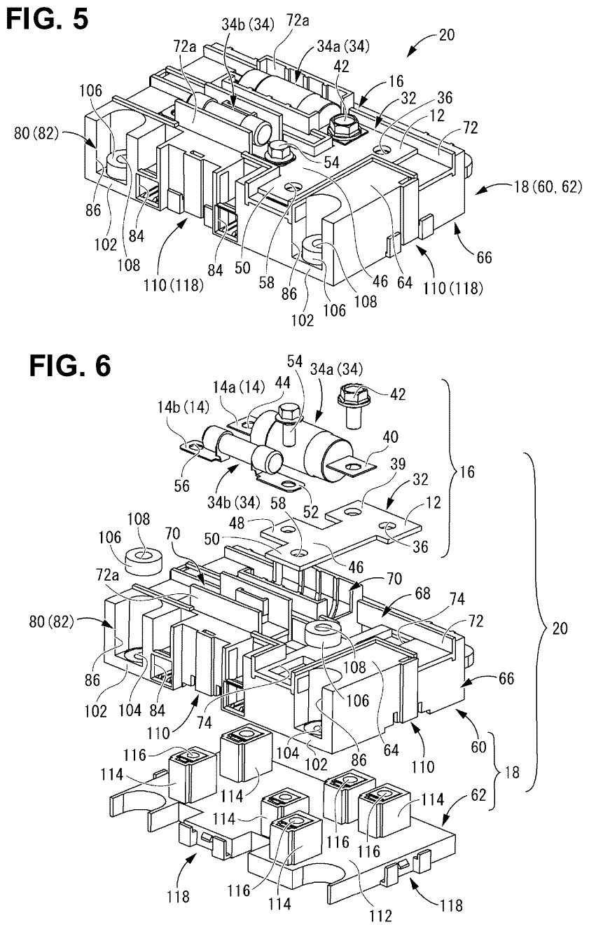

Also, as depicted in FIGS. 5 and 6, the basic branch circuit 16 is configured to include a basic bus bar 32 as a bus bar and fuses 34. The basic bus bar 32 and the fuses 34 are connected, and in this first embodiment, a first fuse 34a and a second fuse 34b are used as the fuses 34 connected to the basic bus bar 32. In particular, although the first fuse 34a is larger than the second fuse 34b in this first embodiment, when a plurality of fuses are connected to the basic bus bar, it is possible to use fuses of different sizes and possible to use fuses of the same size.

The basic bus bar 32 as a whole is in the shape of a substantially rectangular plate that extends in the front-rear direction and is formed of a metal with superior electrical conductivity. A part where the width dimension (the left-right dimension) is increased is provided at one end in the length direction (that is, the rear end) of the basic bus bar 32, with the basic-side input portion 12 being formed at a right side end of this rear end part. A bolt insertion hole 36 that passes through the basic bus bar 32 in the plate thickness direction (that is, the vertical direction) is formed in the basic-side input portion 12, and as one example, by placing a terminal (not illustrated) provided at an end of an electric wire that extends from the battery pack on the basic-side input portion 12 and fixing the terminal with a bolt 38 (as indicated by chain double-dashed lines in FIGS. 1 and 2), the battery pack and the basic bus bar 32 are electrically connected.

A first connecting portion 39 is formed at a left-side end of the rear end part of the basic bus bar 32. This first connecting portion 39 and the input terminal 40 of the first fuse 34a are placed on each other and fixed by a bolt 42. The first fuse 34a is disposed so as to extend in the left-right direction, and a first basic-side output portion 14a of the basic-side output portion 14 is constructed by an output terminal provided on the opposite side (that is, the left side) of the first fuse 34a to the input terminal 40. A bolt insertion hole 44 that passes through in the thickness direction (that is, the vertical direction) is formed in the first basic-side output portion 14a and as one example, by placing a terminal (not illustrated) provided at an end of an electric wire that extends from an accessory on the first basic-side output portion 14a and fixing the terminal with a bolt 38, an accessory and the first fuse 34a are electrically connected. That is, a power path that includes the first connecting portion 39 and the first fuse 34a and extends from the basic-side input portion 12 to the first basic-side output portion 14a is constructed in the basic branch circuit 16.

The other end (or “front side”) in the length direction of the basic bus bar 32 constructs a power path that branches from the power path that extends from the basic-side input portion 12 to the first basic side output portion 14a, with a basic-side branch connecting portion 46 being constructed at the other end in the length direction (or “front end”) of the basic bus bar 32. The basic-side branch connecting portion 46 is provided with a second connecting portion 48, which extends to the left, and a third connecting portion 50, which extends forward.

An input terminal 52 of the second fuse 34b is placed on the second connecting portion 48 and fixed with a bolt 54. The second fuse 34b is disposed so as to extend in the left-right direction, and a second basic-side output portion 14b of the basic-side output portion 14 is constructed by an output terminal provided on the opposite side (that is, the left side) of the second fuse 34b to the input terminal 52. A bolt insertion hole 56 that passes through in the thickness direction (that is, the vertical direction) is formed in the second basic-side output portion 14b, and as one example, by placing a terminal (not illustrated) provided at an end of an electric wire that extends from a different accessory to the accessory connected to the first fuse 34a on the second basic-side output portion 14b and fixing the terminal with a bolt 38, the other accessory and the second fuse 34b are electrically connected. That is, a power path that includes the second connecting portion 48 and the second fuse 34b and extends from the basic-side input portion 12 to the second basic-side output portion 14b is constructed in the basic branch circuit 16.

A bolt insertion hole 58 that passes through in the thickness direction (that is, the vertical direction) is formed in the third connecting portion 50. As described later, the third connecting portion 50 of the basic-side branch connecting portion 46 is connected to the additional-side input portion 22 of an additional branch circuit 26.

### Basic Case 18

The basic branch circuit 16 is held on the basic case 18, and in this first embodiment, the basic case 18 is constructed of an upper basic case 60 and a lower basic case 62 that can be assembled in the vertical direction. As one example, the basic case 18 (that is, the upper basic case 60 and the lower basic case 62) is formed of a synthetic resin that is electrically insulating.

The upper basic case 60 as a whole is substantially box-like in shape and open to below, and is substantially rectangular when viewed from above. That is, the upper basic case 60 has a substantially rectangular upper bottom wall portion 64 and a peripheral wall portion 66 that protrudes downward from an outer edge of the upper bottom wall portion 64. A bus bar housing portion 68 that is capable of housing the basic bus bar 32 and fuse housing portions 70 that are capable of housing the first and second fuses 34a and 34b are provided on the upper surface of the upper bottom wall portion 64. The upper bottom wall portion 64 is also provided with vertical wall portions 72 that extend in the vertical direction along paths from the basic-side input portion 12 to the basic-side output portion 14 (that is, the first and second basic-side output portions 14a and 14b) and to the basic-side branch connecting portion 46 (that is, the third connecting portion 50). In particular, parts of the vertical wall portion 72a that construct the fuse housing portions 70 have a larger vertical dimension than the other parts of the vertical wall portions 72 and protrude further upward.

In addition, through windows 74 that pass through in the vertical direction are formed at positions on the upper bottom wall portion 64 corresponding to the bolt insertion holes (as examples the bolt insertion holes 36, 44, 56, and 58) provided in the basic bus bar 32 and the first and second fuses 34a and 34b. Due to this, when the upper basic case 60 and the lower basic case 62 are assembled, nuts 116, described later, provided on the lower basic case 62 become exposed to an upper surface of the basic case 18 through the respective through windows 74.

In addition, a wall at the rear that constructs the peripheral wall portion 66 is provided with leg portions 76 that protrude to the rear. In this first embodiment, a pair of leg portions 76 are provided so as to be spaced apart each other in the left-right direction, with each leg portion 76 being provided with a bolt insertion hole 78 that passes through in the vertical direction.

As described later, an additional case 28 can be linked to the front of the basic case 18, and a front wall that constructs the peripheral wall portion 66 is provided with a first linked portion 80 to which a linking portion 138 provided on an additional case 28 can be linked. In the first embodiment, the linking portion 138 is configured to include convex portions 140 that protrude outward from a surface of the additional case 28, and the first linked portion 80 includes concave portions 82 that are open in the surface of the basic case 18 and capable of housing the convex portions 140. As a particular example, in the first embodiment, the convex portions 140 include a first convex portion 142 and a second convex portion 144, and the concave portions 82 include a first concave portion 84 capable of housing the first convex portion 142 and a second concave portion 86 capable of housing the second convex portion 144. The first and second concave portions 84 and 86 are formed so as to be recessed rearward from the front wall that constructs the peripheral wall portion 66, with the first and second concave portions 84 and 86 both being open at the front.

As also depicted in FIGS. 3 to 6, the first concave portions 84 are provided in the middle in the left-right direction of a lower part of the front wall that constructs the peripheral wall portion 66, and in this first embodiment, two first concave portions 84, 84 are provided so as to be spaced apart from each other in the left-right direction. Each of these first concave portions 84 is substantially rectangular in cross section and extends in the front-rear direction with a predetermined length dimension. That is, an upper wall 88, a lower wall 90, and left and right side walls 92, 92, which construct each first concave portion 84, are integrally formed with the peripheral wall portion 66, with the areas surrounded by these walls 88, 90, 92, 92 acting as the first concave portions 84. That is, each of the walls 88, 90, 92, and 92 has a part that extends in the front-rear direction. Note that spaces (or gaps) are provided above and on both the left and right sides of the upper wall 88, which enable the upper wall 88 to elastically deform in the vertical direction.

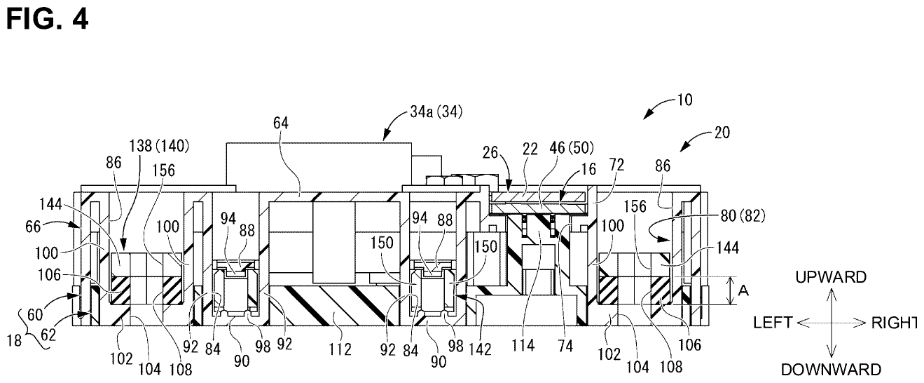

As depicted in FIGS. 3 and 4, an engagement claw portion 94 that protrudes downward is provided in the middle in the front rear direction of the upper wall 88. A through hole 96 that is substantially rectangular and passes through in the vertical direction is also formed in the rear part of the lower wall 90. In addition, the lower wall 90 is provided with a protrusion 98 that protrudes upward and extends in the front-rear direction. In this first embodiment, two protrusions 98, 98 are provided so as to be spaced apart each other in the left-right direction. Each protrusion 98 is substantially semicircular in cross section, and as described later, when a first convex portion 142 is inserted into a first concave portion 84, the first convex portion 142 can be smoothly slid on these protrusions 98.

Also, as depicted in FIGS. 4 to 6, in the first embodiment, two second concave portions 86, 86 are provided at left and right ends of the wall at the front that constructs the peripheral wall portion 66. Each of these second concave portions 86 is substantially semicircular in cross section when viewed from above, is shaped to appear carved out from the front toward the rear, and has a predetermined dimension in the front-rear direction. Left and right side walls 100 and a bottom wall 102 that construct each second concave portion 86 are integrally formed in the peripheral wall portion 66, with each second concave portion 86 being open to the front and to above. A bolt insertion hole 104 that passes through in the vertical direction is formed in approximately the center of each bottom wall 102.

In this first embodiment, a rubber bushing 106 is provided on the bottom wall 102 of each second concave portion 86 as an elastic member made of an elastic material, such as rubber. The rubber bushing 106 is a ring-shaped member with a predetermined dimension in the vertical direction and has a bolt insertion hole 108, which passes through the rubber bushing 106 in the vertical direction, formed in the center. Each rubber bushing 106 is placed on the bottom wall 102 of each second concave portion 86 and is fixed to each bottom wall 102 as necessary so that the bolt insertion holes 104 and 108 communicate with each other in the vertical direction. Note that in the provisionally fixed state depicted in FIGS. 1 to 4, the respective rubber bushings 106 have slight spacings or “zero contact” (that is, no spacing) from second convex portions 144, described later, of an additional unit 30 and are not compressed in the vertical direction, so that the rubber bushings 106 have a predetermined dimension A in the vertical direction (see FIG. 4).

At the lower end of the peripheral wall portion 66, a locking portion 110, which engages a locked portion 118, described later, provided on the lower basic case 62, is provided at a position that is separated from the leg portions 76 and the first linked portion 80 (the respective first concave portions 84 and the second concave portions 86) in circumferential direction.

The lower basic case 62 as a whole is substantially plate-shaped and is shaped so as to fit into the lower opening of the upper basic case 60. That is, the lower basic case 62 is provided with a base portion 112 that is substantially rectangular when viewed from above. A plurality of nut supporting portions 114, which protrude upward, are provided at predetermined positions on the base portion 112, with a nut 116 provided at the upper end of each nut supporting portion 114. In addition, the locked portion 118, which engages with the locking portion 110 on the upper basic case 60, is provided at a position corresponding to the locking portion 110 on the outer circumferential surface of the base portion 112.

### Basic Unit 20

The upper basic case 60 and the lower basic case 62 described above are assembled together in the vertical direction to form the basic case 18. In a state where the upper basic case 60 and the lower basic case 62 have been assembled together, the nut supporting portions 114 are inserted through the through windows 74 provided in the upper bottom wall portion 64 so that the nuts 116 become exposed at the upper surface of the basic case 18. After this, by mounting the basic bus bar 32 and the first and second fuses 34a and 34b in the bus bar housing portion 68 and the fuse housing portions 70 of the upper basic case 60 and fastening the bolts 42 and 54 to the nuts 116, the basic branch circuit 16 is held on the basic case 18 to construct the basic unit 20.

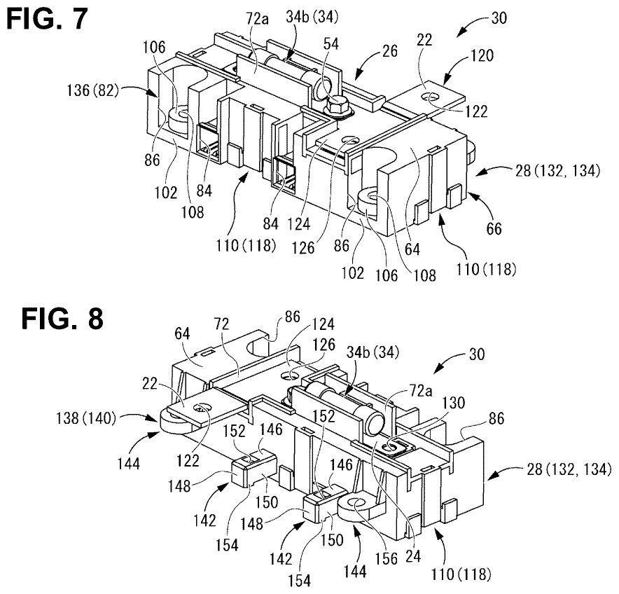

The additional units 30 that are combined with the basic unit 20 will now be described. Although the first additional unit 30a and the second additional unit 30b are used as the additional units 30 in FIGS. 1 to 4, even when a plurality of additional units 30 are used, each additional unit 30 will have the same shape, and for this reason, one additional unit 30 is depicted in FIGS. 7 to 9 and is described below.

### Additional Branch Circuit 26

As depicted in FIGS. 7 to 9, the additional branch circuit 26 is configured to include an additional bus bar 120 as a bus bar and a fuse 34. Note that there are no particular limitations on the fuse 34 connected to the additional bus bar 120, and in this first embodiment, a fuse that is the same as the second fuse 34b connected to the basic bus bar 32 is used. For convenience in the following explanation, the fuse 34 connected to the additional bus bar 120 is also referred to as the “second fuse 34b”.

The additional bus bar 120 as a whole is in the shape of a substantially rectangular plate that extends in the front-rear direction and, in the same way as the basic bus bar 32, is formed of a metal with superior electrical conductivity. The additional-side input portion 22 is constructed at one end in the length direction (that is, the rear end) of the additional bus bar 120, and a bolt insertion hole 122, which passes through the additional bus bar 120 in the plate thickness direction (that is, the vertical direction) is formed in the additional-side input portion 22. In addition, an additional-side branch connecting portion 124 is constructed at the other end in the length direction (that is, the front end) of the additional bus bar 120, and a bolt insertion hole 126, which passes through the additional bus bar 120 in the plate thickness direction (that is, the vertical direction) is formed in the additional-side branch connecting portion 124.

Note that a rear part (that is, the “additional-side input portion 22”) of the additional bus bar 120 is positioned higher than a front part (that is, the “additional-side branch connecting portion 124”). By doing so, as described later, when an additional unit 30 is linked to the basic unit 20 for example, the additional-side input portion 22 is placed on the third connecting portion 50 of the basic-side branch connecting portion 46 from above so that the respective bolt insertion holes 58 and 122 communicate with each other and can be fixed by the bolt 38. This means that by fixing the additional-side input portion 22 and the third connecting portion 50 of the basic-side branch connecting portion 46 using the bolt 38, the additional-side input portion 22 and the third connecting portion 50 of the basic-side branch connecting portion 46 can be connected.

When an extra additional unit 30 (for example, the second additional unit 30b) is linked to another additional unit 30 (for example, the first additional unit 30a), the additional-side input portion 22 of the extra additional unit 30 is placed on the additional-side branch connecting portion 124 of the other additional unit 30 from above so that the respective bolt insertion holes 122 and 126 communicate with each other and can be fixed by the bolt 38. This means that by fixing the additional-side input portion 22 and the additional-side branch connecting portion 124 using the bolt 38, the additional-side input portion 22 and the additional-side branch connecting portion 124 can be connected.

Note that although connected parts of the additional-side input portion 22 and the third connecting portion 50 of the basic-side branch connecting portion 46 and/or connected parts of the additional-side input portion 22 and the additional-side branch connecting portion 124 may be simply fixed with a bolt 38, it is also possible to electrically connect the battery pack to such connected parts by placing a terminal, not illustrated, provided at the end of a wire that extends from the battery pack on the additional-side input portion 22 and fixing the terminal with a bolt 38.

An additional connecting portion 128, which protrudes to the left, is provided on the additional bus bar 120 between the additional-side input portion 22 and the additional-side branch connecting portion 124 in the front-rear direction, or in more detail, toward one end in the length direction (here, the rear end) of the additional bus bar 120 than the additional-side branch connecting portion 124. This additional connecting portion 128 and the input terminal 52 of the second fuse 34b are placed over each other and fixed by a bolt 54. The second fuse 34b is disposed so as to extend in the left-right direction, and the additional-side output portion 24 is constructed by an output terminal provided on the opposite side (that is, the left side) of the second fuse 34b to the input terminal 52. A bolt insertion hole 130 that passes through in the thickness direction (that is, the vertical direction) is formed in the additional-side output portion 24, and as one example, by placing a terminal, not illustrated, provided at the end of an electric wire that extends from another accessory aside from the accessory that is electrically connected to the basic branch circuit 16 (that is, the first and second fuses 34a and 34b) on the additional-side output portion 24 and fixing with a bolt 38, the other accessory is electrically connected to the second fuse 34b in the additional branch circuit 26.

### Additional Case 28

The additional branch circuit 26 is held on the additional case 28, and in this first embodiment, the additional case 28 is constructed of an upper additional case 132 and a lower additional case 134 that can be assembled in the vertical direction. As one example, the additional case 28 (that is, the upper additional case 132 and the lower additional case 134) is formed of a synthetic resin that is electrically insulating. The structures of the upper additional case 132 and the lower additional case 134 of the additional case 28 are fundamentally the same as the structures of the upper basic case 60 and the lower basic case 62 respectively of the basic case 18. For this reason, in the upper additional case 132 and the lower additional case 134, structures and parts that are substantially the same as those of the upper basic case 60 and the lower basic case 62 have been assigned the same reference numerals in the drawings as in the upper basic case 60 and the lower basic case 62.

The upper additional case 132 is equipped with an upper bottom wall portion 64, which is substantially rectangular, and a peripheral wall portion 66 that protrudes downward from an outer edge of the upper bottom wall portion 64. A bus bar housing portion 68 that is capable of housing the additional bus bar 120 and a fuse housing portion 70 that is capable of housing the second fuse 34b are provided on the upper surface of the upper bottom wall portion 64. Vertical wall portions 72 (whose parts that construct the fuse housing portion 70 are vertical wall portions 72a) which extend in the vertical direction are provided on the upper bottom wall portion 64 along a path from the additional-side input portion 22 to the additional-side output portion 24. Through windows 74 that pass through in the vertical direction are also provided at predetermined positions in the upper bottom wall portion 64.

In the wall at the front that constructs the peripheral wall portion 66, a second linked portion 136, which can be linked to the linking portion 138 (described later) provided on an additional case 28, is provided as openings in the surface of the additional case 28. This second linked portion 136 is a similar structure to the first linked portion 80 provided on the basic case 18. That is, the second linked portion 136 is configured to include the concave portions 82, with these concave portions 82 including the first concave portions 84 and the second concave portions 86. In this first embodiment, in the wall at the front that constructs the peripheral wall portion 66 of the upper additional case 132, two first concave portions 84, 84 are provided in the middle in the left-right direction so as to be spaced apart from each other in the left-right direction, and second concave portions 86, 86 are provided at both ends in the left-right direction.

Note that when a plurality of additional units 30 are provided, the rubber bushings 106 are not placed on the bottom walls 102 in the respective second concave portions 86 of the additional unit 30 positioned at the front (in the branch circuit unit 10 depicted in FIGS. 1 to 4, the second additional unit 30b). Rubber bushings 106 are placed however on the bottom walls 102 of the respective second concave portions 86 of each additional unit 30 positioned between the basic unit 20 and the additional unit 30 at the front (in the branch circuit unit 10 depicted in FIGS. 1 to 4, the first additional unit 30a).

In addition, as depicted in FIG. 8, in the upper additional case 132, the linking portion 138 that can be linked to the basic case 18 or to another additional case 28 is provided on a wall at the rear that constructs the peripheral wall portion 66. The linking portion 138 is configured to include the convex portions 140 that protrude outward from the surface of the additional case 28, and in this first embodiment, the convex portions 140 are configured to include first convex portions 142 and second convex portions 144. The first convex portions 142 and the second convex portions 144 are formed so as to protrude to the rear from a wall at the rear that constructs the peripheral wall portion 66.

The first convex portions 142 are provided in the middle in the left-right direction of a lower part of the rear wall that constructs the peripheral wall portion 66, and in the first embodiment, two first convex portions 142, 142 are provided so as to be spaced apart from each other in the left-right direction. Each of these first convex portions 142 has an outer shape that is substantially cuboid and extends with a predetermined length dimension in the front-rear direction. That is, an upper wall 146, a rear wall 148, and left and right-side walls 150, 150, which construct each first convex portion 142, are integrally formed with the peripheral wall portion 66, with each first convex portion 142 being open to below. That is, each of the walls 146, 148, 150, and 150 includes a part that extends in the front-rear direction, and the rear wall 148 and both left and right side walls 150 and 150 protrude downward from a peripheral edge of the upper wall 146.

As depicted in FIGS. 3 and 8, an engagement hole 152, which passes through in the vertical direction and is capable of engaging the engagement claw portion 94 that protrudes downward in a first concave portion 84, is formed in the middle in the front-rear direction of the upper wall 146. An engagement portion 154, which protrudes downward, is provided at the rear end of each first convex portion 142. That is, each engagement portion 154 is configured so that the distance by which the engagement portion 154 protrudes downward from the upper wall 146 is larger at the rear wall 148 and at the rear ends of the side walls 150 than at other parts of the side walls 150.

In the first embodiment, the two second convex portions 144, 144 are provided at predetermined height positions at both left and right ends of the rear wall that constructs the peripheral wall 66. Each second convex portion 144 is substantially semicircular in cross section when viewed from above and has predetermined dimensions in the front-rear and vertical directions. A bolt insertion hole 156, which passes through in the vertical direction, is formed in substantially the center of each second convex portion 144.

In addition, a locking portion 110 is provided at a position at a lower end of the peripheral wall portion 66 that is separated from the second linked portion 136 (that is, the first concave portions 84 and the second concave portions 86) and the linking portion 138 (that is, the first convex portions 142 and the second convex portions 144) in the circumferential direction.

The lower additional case 134 as a whole is substantially plate-shaped and is shaped to fit into the lower opening of the upper additional case 132. That is, the lower additional case 134 is provided with a base portion 112 that is substantially rectangular when viewed from above and has a plurality of nut supporting portions 114, each of which is provided with a nut 116 at an upper end, provided at predetermined positions on the base portion 112. In addition, a locked portion 118 is provided on the outer circumferential surface of the base portion 112 at a position corresponding to the locking portion 110.

### Additional Unit 30

The additional case 28 is formed by assembling the upper additional case 132 and the lower additional case 134 described above together in the vertical direction. In a state where the upper additional case 132 and the lower additional case 134 have been assembled, the nut supporting portions 114 are inserted through the through windows 74 provided in the upper bottom wall portion 64 so that the nuts 116 become exposed at the top surface of the additional case 28. The additional bus bar 120 and the second fuse 34b are mounted in the bus bar housing portion 68 and the fuse housing portion 70 of the upper additional case 132, and by fastening the bolt 54 to the nut 116, the additional branch circuit 26 is held in the additional case 28 to construct the additional unit 30. Note that in the additional unit 30, the rear part (or additional-side input portion 22) of the additional bus bar 120 protrudes to the rear from the upper bottom wall portion 64 of the additional case 28.

### Method of Assembling the Branch Circuit Unit 10

A specific example of a method of assembling the branch circuit unit 10 will now be described. Note that the method of assembling the branch circuit unit 10 is not limited to the embodiment described below.

First, the lower basic case 62, with the nuts 116 placed on the nut supporting portions 114, is brought close to the upper basic case 60 from below and the locking portion 110 is placed in engagement with the locked portion 118 to assemble the upper basic case 60 and the lower basic case 62. By doing so, the basic case 18 is completed. The basic bus bar 32 and the first and second fuses 34a and 34b are mounted in the bus bar housing portion 68 and the respective fuse housing portions 70 of the basic case 18, and the bolts 42 and 54 are fastened to the nuts 116. The rubber bushings 106 are also placed on each bottom wall 102 of the second concave portions 86 and attached as necessary. By doing so, the basic unit 20 is completed.

After this, the lower additional case 134, with the nuts 116 placed on the nut supporting portions 114, is brought close to the upper additional case 132 from below and the locking portion 110 is placed in engagement with the locked portion 118 to assemble the upper additional case 132 and the lower additional case 134. By doing so, the additional case 28 is completed. The additional bus bar 120 and the second fuse 34b are mounted in the bus bar housing portion 68 and the fuse housing portion 70 of this additional case 28, and the bolt 54 is fastened to the nut 116. As necessary, the rubber bushings 106 are placed on and attached to the respective bottom walls 102 of the second concave portions 86. By doing so, each additional unit 30 (that is, the first and second additional units 30a and 30b) is completed.

After this, as depicted in FIG. 10, the linking portion 138 of the first additional unit 30a is linked to the first linked portion 80 of the basic unit 20 to assemble the basic unit 20 and the first additional unit 30a. In more detail, the first convex portions 142 of the first additional unit 30a are inserted into the first concave portions 84 of the basic unit 20 and the second convex portions 144 of the first additional unit 30a are inserted into the second concave portions 86 of the basic unit 20. By inserting the first convex portions 142 into the first concave portions 84, the first convex portions 142 slide to the rear on the protrusions 98 and the front ends of the upper walls 146 are placed in contact with the engagement claw portions 94.

By then pressing the first additional unit 30a further into the basic unit 20, each upper wall 88 elastically deforms upward, which enables further insertion of the first convex portions 142 into the first concave portions 84. After this, the engagement claw portions 94 enter the engagement holes 152, which causes the upper walls 88 to elastically return to their original shapes with the engagement claw portions 94 in engagement with the engagement holes 152. By doing so, movement of the first convex portions 142 from the first concave portions 84 in a direction that causes detachment is prevented and the basic unit 20 (that is, the basic case 18) and the first additional unit 30a (that is, the additional case 28) become linked in a provisionally fixed state. As a result, a branch circuit unit 10′ provided with three output portions (that is, the first and second basic-side output portions 14a and 14b and the additional-side output portion 24) is completed in a state where the basic unit 20 and the first additional unit 30a are provisionally fixed. Note that as described earlier, when the basic unit 20 and the first additional unit 30a are in the provisionally fixed state, the rubber bushings 106 on the second concave portions 86 are not compressed in the vertical direction and have a predetermined vertical dimension A.

In this way, in a state (the “branch circuit unit 10”) where the basic unit 20 and the first additional unit 30a have been linked, the additional-side input portion 22 of the additional branch circuit 26 that protrudes to the rear from the additional case 28 is placed on the third connecting portion 50 of the basic-side branch connecting portion 46 of the basic branch circuit 16 from above so that the respective bolt insertion holes 122 and 58 communicate with each other in the vertical direction. By inserting a bolt 38 through these bolt insertion holes 122 and 58 and fastening the bolt 38 to a nut 116, the additional side input portion 22 and the basic-side branch connecting portion 46 are placed on each other in an electrically conductive state. This means that by linking the linking portion 138 and the first linked portion 80, the basic-side branch connecting portion 46 becomes disposed so as to be connectable to the additional-side input portion 22 of an additional branch circuit 26.

After this, the linking portion 138 of the second additional unit 30b is linked to the second linked portion 136 of the first additional unit 30a of the branch circuit unit 10′, thereby assembling the first additional unit 30a and the second additional unit 30b. Note that since the operation of linking the second linked portion 136 and the linking portion 138 is the same as the operation of linking the first linked portion 80 and the linking portion 138 described above, description is omitted here. Through this operation, the first additional unit 30a and the second additional unit 30b become linked in a provisionally fixed state. As a result, as depicted in FIG. 1, the branch circuit unit 10 provided with four output portions (that is, first and second basic side output portions 14a and 14b, the additional-side output portion 24 of the first additional unit 30a, and the additional-side output portion 24 of the second additional unit 30b) is completed in a state where the basic unit 20 and the first additional unit 30a, and the first additional unit 30a and the second additional unit 30b, are provisionally fixed.

In this branch circuit unit 10, like the branch circuit unit 10′ described earlier, in addition to the rubber bushings 106 of the basic unit 20, the rubber bushings 106 in the first additional unit 30a are similarly not compressed in the vertical direction and have a predetermined vertical dimension A. In a state where the first additional unit 30a and the second additional unit 30b have been linked, the additional side input portion 22 of the additional branch circuit 26 that protrudes to the rear from the second additional unit 30b is placed on the additional-side branch connecting portion 124 of the first additional unit 30a from above so that the respective bolt insertion holes 122 and 126 communicate with each other in the vertical direction. By inserting a bolt 38 through these bolt insertion holes 122 and 126 and fastening the bolt 38 to a nut 116, the additional side input portion 22 and the additional-side branch connecting portion 124 are placed on each other in an electrically conductive state. This means that by linking the linking portion 138 and the second linked portion 136, the additional-side branch connecting portion 124 of one additional unit (here, the first additional unit 30a) is disposed so as to be connectable to the additional-side input portion 22 of another additional unit (here, the second additional unit 30b).

For the branch circuit unit 10 manufactured in this way, a terminal (not illustrated) provided at the end of an electric wire that extends from a battery pack, for example, is placed on the basic-side input portion 12 of the basic unit 20 and the bolt 38 is fastened. At a part where the third connecting portion 50 of the basic-side branch connecting portion 46 and the additional-side input portion 22 are placed over each other, the bolt 38 is inserted through the bolt insertion holes 58 and 122 and fastened. In the same way, at the part where the additional-side branch connecting portion 124 and the additional-side input portion 22 are placed over each other, the bolt 38 is inserted through and fastened to the respective bolt insertion holes 126 and 122. Note that a terminal, not illustrated, provided at the end of an electric wire that extends from the battery pack may be placed on the coinciding parts of the third connecting portion 50 and the additional-side input portion 22 and/or the coinciding parts of the additional-side branch connecting portion 124 and the additional-side input portion 22 and fastened with a bolt 38.

Terminals, not illustrated, provided at the ends of wires that extend from respectively different accessories are placed on the four output portions (that is, the first and second basic-side output portions 14a and 14b, the additional-side output portion 24 of the first additional unit 30a, and the additional-side output portion 24 of the second additional unit 30b) provided in the branch circuit unit 10 and fastened with bolts 38. By doing so, power paths from the battery pack to the respective accessories are produced with the required number of branches.

In the branch circuit unit 10 in the provisionally fixed state described above, the bottom walls 102 of the second concave portions 86 of the basic unit 20 and the second convex portions 144 of the first additional unit 30a are placed over each other with the rubber bushings 106 in between, and the respective bolt insertion holes 104, 108, and 156 are aligned to communicate with each other in the vertical direction. In the same way, the bottom walls 102 of the second concave portions 86 of the first additional unit 30a and the second convex portions 144 of the second additional unit 30b are placed over each other with the rubber bushings 106 in between, and the respective bolt insertion holes 104, 108, and 156 are aligned to communicate with each other in the vertical direction. In addition to the bolt insertion holes 104, 108, and 156, the bolts 38 are inserted through and fastened to the bolt insertion holes 78 and 104 provided in the leg portions 76 of the basic unit 20 and the bottom wall 102 of each second concave portion 86 in the additional unit 30 positioned at the front (here, the second additional unit 30b) to fix the branch circuit unit 10 inside the case of the battery pack or in the vicinity of the battery pack, for example. By doing so, the basic unit 20 and the first additional unit 30a, and the first additional unit 30a and the second additional unit 30b, are placed in a fully fixed state.

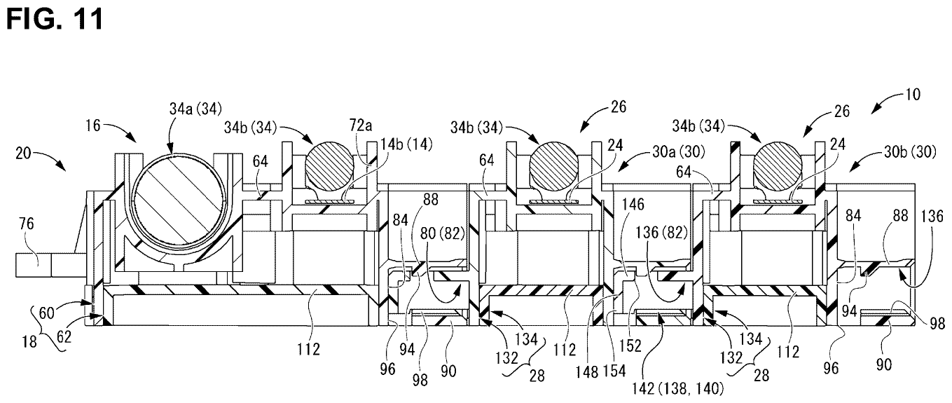

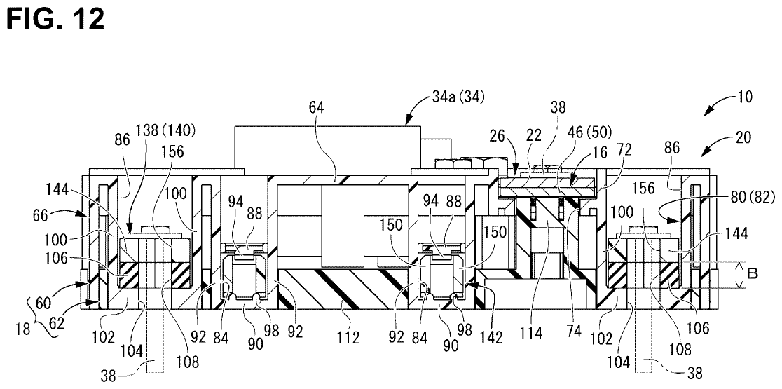

As depicted in FIGS. 11 and 12, the upper basic case 60 and the lower basic case 62, and each upper additional case 132 and lower additional case 134 become closer together in the vertical direction in the fully fixed state than in the provisionally fixed state depicted in FIGS. 3 and 4. As depicted in FIG. 11, this increases the alignment in the front-rear direction between the engagement portions 154 provided at the rear ends of the first convex portions 142 and the protrusions 98 provided on the lower walls 90 of the first concave portions 84, and enables the engagement portions 154 to enter into the through holes 96, for example. By doing so, detachment of the first convex portions 142 from the first concave portions 84 is more reliably prevented. Note that at this time, the engagement between the engagement claw portions 94 and the engagement holes 152 may be released and the engagement claw portions 94 may come out of the engagement holes 152.

As depicted in FIG. 12, by inserting the bolts 38 through the parts where the bottom walls 102 of the second concave portions 86 and the second convex portions 144 have been placed over each other with the rubber bushings 106 in between and fastening the bolts 38, the bottom walls 102 and the second convex portions 144 are placed in contact via the rubber bushings 106. By fastening the bolts 38 in this way, the rubber bushings 106 become compressed in the vertical direction between the bottom walls 102 and the second convex portions 144, which results in a vertical dimension B (see FIG. 12) that is smaller than the vertical dimension A. In this way, by fixing the bottom walls 102 and the second convex portions 144 via the rubber bushings 106, tolerances can be absorbed and the operation of fastening the bolts can be performed stably.

With the branch circuit unit 10 according to the first embodiment, when a branch circuit is provided for a plurality of automobiles of different models or grades, even when the required number of output portions differs, for example, it is possible to cope with this situation by linking only the required number of additional units 30 to the basic unit 20, which makes it possible to avoid the production of unused space like in Patent Document 1 described above for example and to also avoid making the branch circuit unit 10 unnecessarily large. In particular, when a plurality of additional units 30 are linked, each additional unit will have the same structure, so that no special processes or the like are required to manufacture the plurality of additional units. Also, when linking a plurality of the additional units 30, it is sufficient to simply repeat the same assembly process, which improves manufacturing efficiency and work efficiency.

The basic unit 20 and one additional unit 30 (the first additional unit 30a) are linked by the first linked portion 80 and the linking portion 138, so that the third connecting portion 50 of the basic-side branch connecting portion 46 and the additional-side input portion 22 become disposed so as to be connectable to each other. When an extra additional unit (that is, the second additional unit 30b) is used, by linking an existing additional unit (here, the first additional unit 30a) and the extra additional unit (here, the second additional unit 30b) using the second linked portion 136 and the linking portion 138, the additional-side branch connecting portion 124 and the additional-side input portion 22 become disposed so as to be connectable to each other. This means that when the units 20, 30a, and 30b are linked, the basic-side branch connecting portion 46 and the additional-side input portion 22, and the additional-side branch connecting portion 124 and the additional-side input portion 22 can be connected by simply fastening a bolt or the like, which improves work efficiency.

The linking portion 138 includes the convex portions 140 that protrude outward from the surface of the additional case 28, and the first linked portion 80 and the second linked portion 136 include the concave portions 82 that are open at the surface of the basic case 18 and the surface of the additional case 28, respectively, and are capable of housing the convex portions 140. By doing so, when linking the linking portion 138 and the first linked portion 80, and the linking portion 138 and the second linked portion 136, the convex portions 140 become housed in the concave portions 82, which means that parts related to linking do not protrude outward and increases in size of the branch circuit unit 10 are avoided. Since the basic unit 20 does not have a linking portion 138 and only has the first linked portion 80, which is composed of the concave portions 82, it is possible to reduce the required space when storing or transporting the basic unit 20, for example.

The convex portions 140 include the first convex portions 142 and the second convex portions 144, and the concave portions 82 include the first concave portions 84, which are capable of housing the first convex portions 142, and the second concave portions 86, which are capable of housing the second convex portions 144. By inserting the first convex portions 142 into the first concave portions 84, the basic unit 20 and the first additional unit 30a, and the first additional unit 30a and the second additional unit 30b are provisionally fixed. By inserting the second convex portions 144 into the second concave portions 86 and fixing with the bolts 38, the basic unit 20 and the first additional unit 30a, and the first additional unit 30a and the second additional unit 30b are fully fixed. In this way, the respective units 20, 30a, and 30b can be stored, transported, and the like in a provisionally fixed state, and the units 20, 30a, and 30b can be placed in the fully fixed state when fixed to a vehicle for actual use. This not only facilitates storage and transportation, but also makes it possible to flexibly accommodate changes in specification immediately before installation, for example.

The basic branch circuit 16 includes a bus bar (the basic bus bar 32), a basic-side input portion 12 is provided at one end (that is, the rear end) of this basic bus bar 32, and a basic-side branch connecting portion 46 is provided at the other end (that is, the front end) of this basic bus bar 32. The input terminal 40 of the first fuse 34a is connected to one end (the rear end) of the basic bus bar 32. In this way, an input portion, a connecting portion for an additional bus bar 120, and a connecting portion for the fuse 34 are constructed on a single bus bar (the basic bus bar 32), which achieves an effect of reducing the number of components.

In the same way, the additional branch circuit 26 includes a bus bar (the additional bus bar 120), the additional-side input portion 22 is provided at one end (the rear end) of this additional bus bar 120, and an additional-side branch connecting portion 124 is provided at the other end (the front end) of this additional bus bar 120. The input terminal 52 of the second fuse 34b is connected to the additional bus bar 120 closer to one end (the rear end) than the additional-side branch connecting portion 124. This also achieves an effect of reducing the number of components, since an input portion, a connecting portion for another additional bus bar 120, and a connecting portion for the fuse 34 (the second fuse 34b) are constructed on a single bus bar (the additional bus bar 120).

The basic branch circuit 16 includes the fuses 34 (the first fuse 34a and the second fuse 34b), and the basic-side output portions 14 (that is, the first basic-side output portion 14a and the second basic-side output portion 14b) are constructed by the output terminals of the fuses 34. By doing so, it is possible to omit the provision of a separate bus bar or the like on the output side of the basic branch circuit 16, to reduce the number of components, and to miniaturize the basic unit 20 and in turn the branch circuit unit 10.

In the same way, the additional branch circuit 26 includes a fuse 34 (the second fuse 34b), with the additional-side output portion 24 being constructed of the output terminal of this second fuse 34b. This also achieves an effect of making it possible to omit the provision of a separate bus bar or the like on the output side of the additional branch circuit 26, to reduce the number of components, and to miniaturize the additional unit 30 and in turn the branch circuit unit 10.

The second convex portions 144 of the linking portion 138 and the bottom walls 102 of the second concave portions 86 of the first linked portion 80 or the second linked portion 136 are placed in contact via the rubber bushings 106 which serve as elastic members. By doing so, the rubber bushings 106 can absorb the tolerances between the second convex portions 144 and the bottom walls 102, which makes it possible to stably fix the second convex portions 144 and the bottom walls 102 with the bolts 38.

### Modifications

Although the first embodiment has been described in detail above as a specific example of the present disclosure, the present disclosure is not limited to the specific description given above. Various modifications, improvements, and the like within a scope of achieving the object of the present disclosure are also included in the present disclosure. As one example, the following example modifications to the embodiment are also included in the technical scope of the present disclosure.

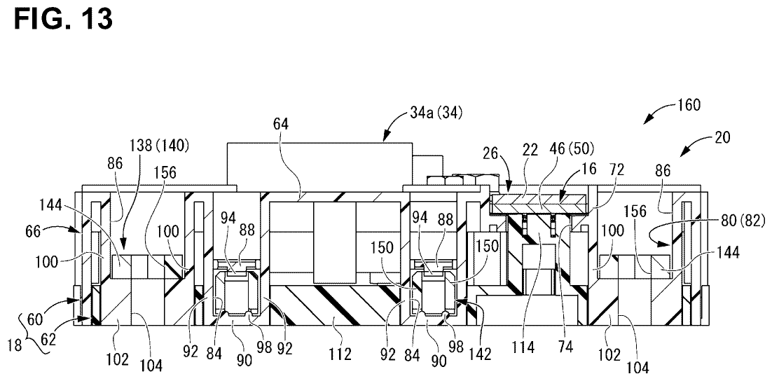

(1) Although a rubber bushing 106 is provided as an elastic member between each bottom wall 102 of each second concave portion 86 and each second convex portion 144 in the embodiment described above, the elastic members are not limited to rubber bushings and may be resin springs or metal springs. When the elastic members are resin springs, the members may be integrally formed with the basic case or the additional case. In addition, although the rubber bushings 106 are attached on the bottom walls 102 of the second concave portions 86 in the embodiment described above, regardless of whether the elastic members are formed integrally with or separately from the basic case and the additional case, the elastic members may be provided on the lower surfaces of the second convex portions. Note that in the branch circuit unit according to the present disclosure, the elastic members are not essential, and similarly to a branch circuit unit 160 depicted in FIG. 13, elastic members do not have to be provided between the bottom walls 102 of the second concave portions 86 and the second convex portions 144, and when the bolts 38 are inserted and fastened to fully fix the units, the bottom walls 102 of the second concave portions 86 and the second convex portions 144 may be placed in direct contact.

(2) Although the basic case 18 is constructed of an upper basic case 60 and a lower basic case 62, and each additional case 28 is composed of the upper additional case 132 and the lower additional case 134 in the embodiment described above, the present disclosure is not limited to this configuration. As one example, since the lower basic case 62 and the lower additional case 134 are intended to simply support the nuts 116, in configurations such as where the nuts are internally housed, the basic case and the additional case may be constructed of single members. When the basic case is constructed of an upper basic case and a lower basic case and/or when each additional case is composed of an upper additional case and a lower additional case, the various members can be housed in any freely chosen arrangement.

(3) Although the fuses 34 (the first fuse 34a and the second fuse 34b) are provided on the basic branch circuit 16 and the additional branch circuit 26 in the above embodiment, the present disclosure is not limited to this configuration. In other words, fuses do not need to be provided in the basic branch circuit and the additional branch circuits, parts that extend to the left from the bus bars (the basic bus bar and the additional bus bar) may be provided, and the left ends of such extending parts may form the basic-side output portion and the additional-side output portion. Alternatively, electrical components such as relays may be disposed in the basic branch circuit and/or the additional branch circuit in place of or in addition to fuses.

(4) Although the branch circuit unit 10 includes one basic unit 20 and two additional units 30 (the first additional unit 30a and the second additional unit 30b) in the embodiment described above, there is no limit on the number of the additional units. As examples, a branch circuit unit 10′ where one additional unit is linked to one basic unit (that is, the state depicted in FIG. 10) may be installed in a vehicle, or a branch circuit unit in which three or more additional units are linked to one basic unit may be installed in a vehicle. When a plurality of additional units are provided, each additional unit has the same structure.

### LIST OF REFERENCE NUMERALS

10 Branch circuit unit (FIG. 1)
10′ Branch circuit unit (FIG. 10)
12 Basic-side input portion
14 Basic-side output portion
14a First basic-side output portion (output terminal)
14b Second basic-side output portion (output terminal)
16 Basic branch circuit
18 Basic case
20 Basic unit
22 Additional-side input portion
24 Additional-side output portion (output terminal)
26 Additional branch circuit
28 Additional case
30 Additional unit
30a First additional unit (one additional unit)
30b Second additional unit (another additional unit)
32 Basic bus bar (bus bar)
34 Fuse
34a First fuse
34b Second fuse
36 Bolt insertion hole
38 Bolt
39 First connecting portion
40 Input terminal
42 Bolt
44 Bolt insertion hole
46 Basic-side branch connecting portion
48 Second connecting portion
50 Third connecting portion
52 Input terminal
54 Bolt
56, 58 Bolt insertion hole
60 Upper basic case
62 Lower basic case
64 Upper bottom wall portion
66 Peripheral wall portion
68 Bus bar housing portion
70 Fuse housing portion
72, 72a Vertical wall portion
74 Through window
76 Leg portion
78 Bolt insertion hole
80 First linked portion
82 Concave portion
84 First concave portion
86 Second concave portion
88 Upper wall
90 Lower wall
92 Side wall
94 Engagement claw portion
96 Through-hole
98 Protrusion
100 Side wall
102 Bottom wall
104 Bolt through hole
106 Rubber bushing (elastic member)
108 Bolt through hole
110 Locking portion
112 Base portion
114 Nut supporting portion
116 Nut
118 Locked portion
120 Additional bus bar (bus bar)
122 Bolt through hole
124 Additional-side branch connecting portion
126 Bolt through hole
128 Additional connecting portion
130 Bolt through hole
132 Upper additional case
134 Lower additional case
136 Second linked portion
138 Linking portion
140 Convex portion
142 First convex portion
144 Second convex portion
146 Upper wall
148 Rear wall
150 Side wall
152 Engagement hole
154 Engagement portion
156 Bolt insertion hole
160 Branch circuit unit (FIG. 13)

1. A branch circuit unit comprising:
a basic unit including a basic branch circuit, which includes a basic-side input portion and a basic-side output portion, and a basic case that holds the basic branch circuit; and
at least one additional unit including an additional branch circuit, which includes an additional-side input portion and an additional-side output portion, and an additional case that holds the additional branch circuit,
wherein the basic case includes a first linked portion to which a linking portion provided on the additional case can be linked, with the basic case and the additional case being linked by linking the linking portion and the first linked portion,
the additional case includes the linking portion and a second linked portion to which a linking portion can be connected,
the basic branch circuit includes a basic-side branch connecting portion connected to the basic-side input portion, with the basic-side branch connecting portion being connected to the additional-side input portion of the additional branch circuit,
the additional branch circuit includes an additional-side branch connecting portion that is connected to the additional-side input portion, and
when a plurality of the additional units are used,
the additional-side branch connecting portion of one additional unit, which is linked to the basic unit-side, is connected to the additional-side input portion of another additional unit, and
the additional case of the one additional unit is linked to the additional case of the other additional unit by linking the linking portion of the other additional unit and the second linked portion of the one additional unit.

2. The branch circuit unit according to claim 1,
wherein by linking the linking portion and the first linked portion, the basic-side branch connecting portion is disposed so as to be connectable to the additional-side input portion of the additional branch circuit, and
when a plurality of the additional units are added,
the additional-side branch connecting portion of the one additional unit is disposed so as to be connectable to the additional-side input portion of the other additional unit by linking the linking portion of the other additional unit and the second linked portion of the one additional unit.

3. The branch circuit unit according to claim 1,
wherein the linking portion includes a convex portion that protrudes outward from a surface of the additional case, and the first linked portion and the second linked portion both include a concave portion that is open at a surface of the basic case and the surface of the additional case, respectively, and is capable of housing the convex portion.

4. The branch circuit unit according to claim 3,
wherein the convex portion includes a first convex portion and a second convex portion, and each concave portion includes a first concave portion and a second concave portion,
the first convex portion provided on the additional case is housed in the first concave portion provided in the basic case or the additional case, and due to the first convex portion and the first concave portion engaging each other, either the basic case and the additional case or two additional cases are held together in a provisionally fixed state, and
either the basic case and the additional case or the two additional cases are placed in a fully fixed state by fastening the second convex portion, which is provided on an additional case, and the second concave portion, which is provided on the basic case or on another additional case, to each other with a bolt.

5. The branch circuit unit according to claim 1,
wherein the basic branch circuit includes a bus bar, and
the basic-side input portion is provided at one end of the bus bar, the basic-side branch connecting portion is provided at another end of the bus bar, and an input terminal of a fuse is connected to the one end side.

6. The branch circuit unit according to claim 1,
wherein the basic branch circuit includes a fuse connected to the basic-side input portion and the basic-side output portion is constructed by an output terminal of the fuse.

7. The branch circuit unit according to claim 1,
wherein the additional branch circuit includes a bus bar, and
the additional-side input portion is provided at one end of the bus bar, the additional-side branch connecting portion is provided at another end of the bus bar, and an input terminal of a fuse is connected to the one end side.

8. The branch circuit unit according to claim 1,
wherein the additional branch circuit includes a fuse connected to the additional-side input portion, and the additional-side output portion is constructed by an output terminal of the fuse.

9. The branch circuit unit according to claim 1,
wherein the linking portion and the first linked portion or the second linked portion contact each other with an elastic member in between.
